(19) United States
(12) Patent Application Publication
(10) Pub. No.: US 2025/0201663 A1
(43) Pub. Date: Jun. 19, 2025

(54) Reflowable Vapor Chamber Lid

(71) Applicant: Marvell Asia Pte Ltd, Singapore (SG)

(72) Inventors: Alaba Bamido, Thousand Oaks, CA (US); Dwayne R. Shirley, Valley Glen, CA (US); Assaad El Helou, Los Angeles, CA (US); Roberto Coccioli, Simi Valley, CA (US)

(21) Appl. No.: 18/983,420

(22) Filed: Dec. 17, 2024

Related U.S. Application Data
(60) Provisional application No. 63/611,734, filed on Dec. 18, 2023.

(51) Int. Cl. H01L 23/427; H01L 21/48; H01L 23/00; H01L 23/552; H01L 25/16

(52) U.S. Cl. CPC H01L 23/427; H01L 21/4871; H01L 23/552; H01L 24/16; H01L 24/26; H01L 24/32; H01L 24/73; H01L 24/81; H01L 25/167; H01L 2224/16225; H01L 2224/26175; H01L 2224/32245; H01L 2224/73253; H01L 2224/8121; H01L 2224/81815; H01L 2924/16151; H01L 2924/16235; H01L 2924/16251

(57) ABSTRACT

An electronic device package, consisting of a planar package substrate defining a package footprint. The package also includes one or more micro-devices surface mounted on and configured to electrically couple to the package substrate via an array of surface mount terminals. A vapor chamber lid overlays the one or more micro-devices and the vapor chamber lid has planar dimensions that are smaller than the package footprint.

### CROSS-REFERENCE TO RELATED APPLICATION

This application claims the benefit of U.S. Provisional Patent Application 63/611,734, filed Dec. 18, 2023, which is incorporated herein by reference.

### FIELD OF THE INVENTION

This invention relates generally to electronic devices, and specifically to the production of electronic devices.

### BACKGROUND OF THE INVENTION

Modern electronic devices typically include electronic components, such as integrated circuits, which generate copious amounts of heat during operation. Consequently, heat management during operation has become an important challenge for the design and manufacture of electronic devices. During fabrication electronic component dies and packages may be placed in a reflow oven which is configured to melt, then cool, pre-positioned solder that is used to form the required electrical connections. Accordingly, heat management mechanisms need also withstand exposure to extreme heating and cooling during device fabrication.

### SUMMARY OF THE INVENTION

An embodiment of the present invention provides an electronic device package, consisting of:
a planar package substrate defining a package footprint;
one or more micro-devices surface mounted on and configured to electrically couple to the package substrate via an array of surface mount terminals; and
a vapor chamber lid overlaying the one or more micro-devices and having planar dimensions that are smaller than the package footprint.

The surface mount terminals may consist of balls arranged in an array.

In a disclosed embodiment the vapor chamber lid has an extension mounted on the substrate, and the extension and the vapor chamber lid may be formed of a common material. The extension and the vapor chamber lid may be formed as a unitary object; alternatively, the extension and the vapor chamber lid are separate objects.

The electronic device package may have stiffeners coupled between the vapor chamber lid and the substrate.

In a further disclosed embodiment the one or more micro-devices include a given micro-device having a surface overlayed by the vapor chamber lid, and the vapor chamber lid has protrusions orthogonal to the surface and enclosing the given micro-device so as to form a containment space for thermal interface material.

In a yet further disclosed embodiment the one or more micro-devices include a given micro-device formed with a mold, and the mold is configured to connect with the vapor chamber lid and with the substrate.

In an alternative embodiment the electronic device package has a thermal interface material (TIM) interposed between and contacting the one or more micro-devices and the vapor chamber lid, and the package further includes TIM retention containment barriers between the lid and the substrate.

In a further alternative embodiment the electronic device package has a coating on a surface of the vapor chamber lid, and the coating is configured to reduce electromagnetic emissions traversing the one or more micro-devices. The one or more micro-devices may consist of a plurality of micro-devices, and the package may include an electromagnetic shield between the plurality of micro-devices that is configured to reduce electromagnetic emissions between the micro-devices.

The vapor chamber lid may consist of a plurality of sub-vapor chamber lids joined and fixedly connected by a mold.

In a yet further alternative embodiment the one or more micro-devices consist of a first micro-device and a second micro-device, and the vapor chamber lid has an aperture aligning with the first micro-device so that the vapor lid contacts the second micro-device without contacting the first micro-device.

In a disclosed embodiment the electronic device package has at least one additional micro-device mounted on and configured to electrically couple to the package substrate via an additional array of surface mount terminals, and the vapor chamber lid overlays the one or more micro-devices without overlaying the at least one additional micro-device. The package may include a thermally conductive lid that is absent a vapor chamber, and that is configured to overlay the at least one additional micro-device. The vapor chamber lid and the thermally conductive lid may have images that are mirror images.

In a further disclosed embodiment the package includes a two-phase flow device, and the vapor chamber lid has a first surface contacting the one or more micro-devices and a second surface contacting the two-phase flow device.

In a yet further disclosed embodiment the vapor chamber lid has a planar section configured to contact surfaces of the one or more micro-devices and at least one tubular section orthogonal to the planar section, and the planar section and the at least one tubular section have a common vapor chamber. The electronic device package may have thermally conductive fins attached to the at least one tubular section.

The one or more micro-devices of the package may consist of only integrated circuits. Alternatively, the one or more micro-devices may have only optoelectronic components. Further alternatively, the one or more micro-devices may consist at least one optoelectronic component and at least one integrated circuit.

There is further provided, according to an embodiment of the present invention, a method, consisting of:
providing a planar package substrate defining a package footprint;
surface mounting one or more micro-devices on the package substrate;
electrically coupling, via an array of surface mount terminals, the one or more micro-devices to the package substrate; and
overlaying a vapor chamber lid on the one or more micro-devices, wherein the vapor chamber lid has planar dimensions that are smaller than the package footprint.

The method may include coupling stiffeners between the vapor chamber lid and the substrate.

The one or more micro-devices may have a given micro-device formed with a mold, and the method may further include connecting the vapor chamber lid and the substrate with the mold.

The vapor chamber lid may consist of a plurality of sub-vapor chamber lids, and the method may further include joining and fixedly connecting the plurality of sub-vapor chamber lids by a mold.

The present disclosure will be more fully understood from the following detailed description of the embodiments thereof, taken together with the drawings, in which:

### BRIEF DESCRIPTION OF THE DRAWINGS

FIG. 1 is a schematic illustration of a process used in producing a micro-device package, according to an embodiment of the present invention;

FIG. 2 shows schematic diagrams of the structure of a vapor chamber lid, according to an embodiment of the present invention;

FIGS. 3A-3G are schematic diagrams of integrated circuit (IC) packages, according to embodiments of the present invention;

FIGS. 4A-4C are schematic diagrams of IC packages comprising multiple dies, according to embodiments of the present invention;

FIGS. 5A and 5B are schematic diagrams of IC packages having a single aperture in a vapor chamber (VC) lid, according to embodiments of the present invention;

FIGS. 6A and 6B are schematic diagrams of IC packages having multiple dies and a partial VC lid, according to embodiments of the present invention;

FIG. 7 is a schematic diagram of an IC package having multiple dies with an attached heatpipe or thermosiphon, according to an embodiment of the present invention;

FIG. 8 is a schematic diagram of an IC package having a die formed with a mold, according to an embodiment of the present invention; and

FIG. 9 is a schematic diagram of an IC package having a finned structure, according to an embodiment of the present invention.

### DETAILED DESCRIPTION OF EMBODIMENTS

### Overview

A micro-device package comprises one or more micro-device dies, such as an integrated circuit (IC) die and/or an optoelectronic die, attached to a shared package substrate. The dies are attached by pads on the lower surface of the dies connecting to pads on the upper surface of the substrate. To connect the pads during package production, solder paste is placed on the pads, and the dies are positioned on the substrate so that the pads on the dies align to pads on the substrate. The assembly is placed in a reflow oven which raises the temperature of the paste, typically to approximately 260° C., causing the paste to reflow and form a liquid solder which wets the pads. The assembly is then cooled, so that the solder solidifies forming a good electrical bond between the pads of the dies and the substrate.

The package may be subjected to more than one reflow process, for example to solder different sections of the package to a motherboard.

During operation of the package, the components of the package may generate considerable heat that raises the temperature of the components. If not prevented, the raised temperature may adversely affect the efficiency of operation of the components, or even lead to their destruction. Consequently, embodiments of the present invention provide a heat sink that dissipates the heat generated during component operation. The heat sink is in the form of a vapor chamber lid that is attached to the upper surface of the dies of the components, and that is configured to withstand the hostile environment of the reflow oven.

The lid, which is formed from a good heat conductor such as copper, comprises a chamber into which a fluid such as water has been introduced. During operation of the micro-devices, the fluid, by means of a phase change, convection, and conduction acts as a heat transfer mechanism having a thermal conductivity significantly larger than that of copper.

The micro-device package thus comprises the one or more dies connected to the package substrate overlaid by the vapor chamber lid. In embodiments of the invention, the package substrate defines a substrate footprint, and the vapor chamber lid is dimensioned to be smaller than the footprint. Making the lid footprint equal in size to, or smaller than, the substrate footprint enables more packages to be processed together in the reflow oven.

In some embodiments the vapor chamber lid is directly connected to the substrate, adding stability to the package.

### DETAILED DESCRIPTION

In the following description, like elements in the drawings are identified by like numerals, and are differentiated as necessary by appending a letter. In addition, all directional references (e.g., upper, lower, upward, downward, left, right, top, bottom, above, below, vertical, and horizontal) are only used for identification purposes to aid the reader's understanding of the present invention, and do not create limitations, particularly as to the position, orientation, or use of embodiments of the invention.

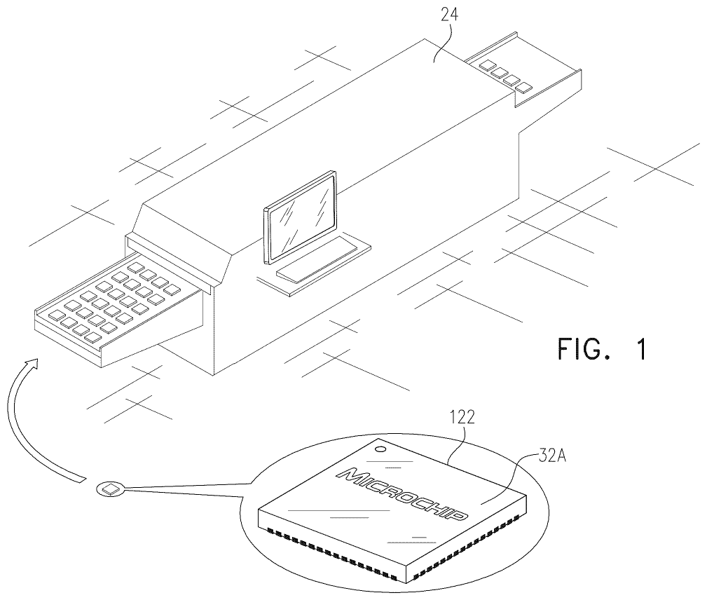

Reference is now made to FIG. 1, which is a schematic illustration of a process used in producing a micro-device package, according to an embodiment of the present invention. The illustration shows a micro-device package 122, in an assembled form, prior to being placed in a reflow oven 24. Package 122, and packages similar to package 122 are described in more detail below. The oven 24 heats then cools the assembled package, so that solder paste of the assembly melts then solidifies to connect elements of the assembly. The reflow process may be applied to the package a number of times before the production process is completed.

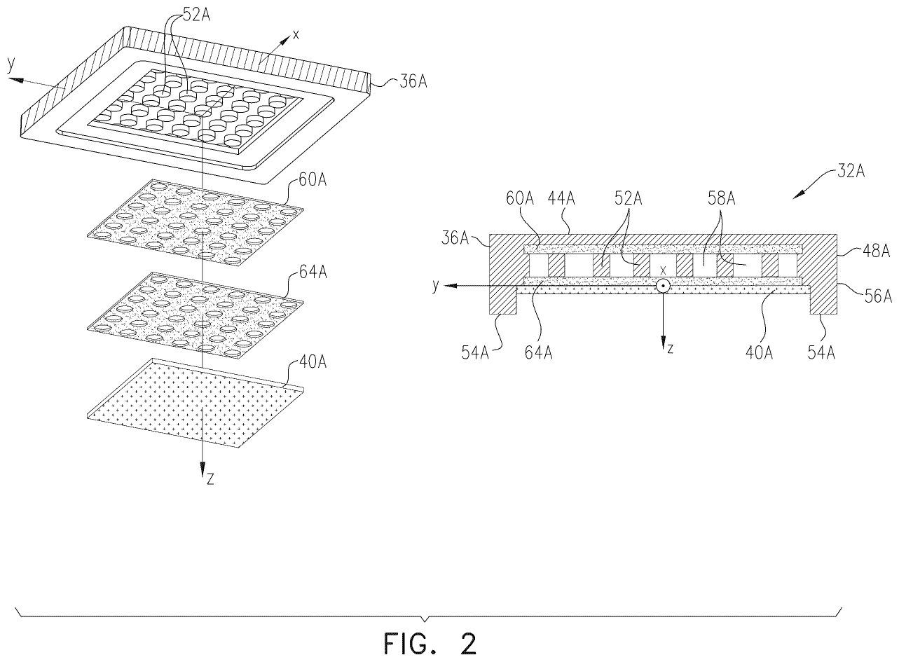

In package 122, a certain level of protection of various heat sensitive micro-device dies is provided by a vapor chamber lid 32A, which is described in more detail below with respect to FIG. 2. In addition to providing the required protection, lid 32A is configured to withstand the reflow process of oven 24.

FIG. 2 shows schematic diagrams of the structure of vapor chamber lid 32A, according to an embodiment of the present invention. The diagrams include an exploded view of the lid, as well as a cross-section of the lid. Lid 32A is, by way of example, in a generally cuboid form and comprises a cup-shaped portion 36A, the cup-shaped portion being closed off by a planar cover 40A. For clarity, the diagrams herein have been drawn on a set of orthogonal xyz axes. The axes are parallel to the edges of portion 36A, with an origin at a center of an inner surface of cover 40A, and the z-axis is normal to cover 40A,

Package 122 may be operated with cup-shaped portion 36A inverted, so that the diagrams show the packages and associated vapor chamber lids, including package 122 and lid 32A, in an inverted orientation.

Cup-shaped portion 36A is formed with a rectangular planar base 44A surrounded by walls 48A, and walls 48A are extended by wall extensions 54A. A plurality of generally similar cylindrical pillars 52A mounted on the base is disposed within a volume enclosed by the walls. The pillars are assumed, by way of example, to have a circular cross-section and to be located at the intersections of a square grid, and to have a height equal to the height of the surrounding walls. Except as described otherwise, cup-shaped portion 3K, and the cup-shaped portions of other vapor chamber lids described herein, comprising a rectangular planar base, a plurality of pillars mounted on the base, and walls and wall extensions surrounding the base, are assumed to be constructed as a unitary object machined from a block of material.

In production of lid 32A planar cover 40A is attached to terminating ends of pillars 52A and to walls 48A of cup-shaped portion 36A, thereby creating an empty internal volume 58A. Sections of pillars 52A and of volume 58A are visible in the cross-section. After the volume has been formed it is at least partially filled with fluid, which acts to transfer heat by convection and as a two-phase closed system in which material phases of the fluid change, i.e., by evaporation from a liquid to a gaseous phase and condensation from the gaseous phase to the liquid phase. Using phase changes enhances the heat transfer because of the fixed temperature maintained during the changes.

The phase changes are further facilitated by plating wicking material on the internal exposed surfaces of base 44A and cover 40A before volume 58A is filled with fluid. The wicking material is illustrated in FIG. 2 as a condenser wick 60A covering a lower surface of base 44A, and an evaporator wick 64A covering an upper surface of cover 40A. The wicking material also surrounds pillars 52A. During operation of lid 32A cover 40A acts as an evaporator of the fluid in volume 58A, and is herein also termed evaporator wall 40A, and base 44A acts as a condenser of the fluid and is herein also termed condenser wall 44A.

Lid 32A is formed in two sections: a vapor chamber (VC) section 56A comprising elements of the lid enclosing volume 58A, and wall extensions 54A. Other lids 32B, 32C, . . . having respective VC sections 56B, 56C, and, unless otherwise stated, wall extensions 54B, 54C, . . . are described hereinbelow. Lids 32A, 32B, 32C, . . . , sections 56A, 56B, 56C, . . . and wall extensions 54A, 54B, 54C, . . . are referred to generically herein as lids 32, sections 56, and wall extensions 54. As necessary, a similar convention is used herein for other elements of lids 32. For example, covers 40A, 40B, 40C, . . . are referred to as covers 40, bases 44A, 44B, 44C, are referred to as bases 44, and pillars 52A, 52B, 52C, are referred to as pillars 52.

While for each lid 32 wicking material, such as condenser wick 60A and evaporator wick 64A, typically covers a lower surface of base 44, an upper surface of cover 40, and surrounds pillars 52, for simplicity the wicking material is not shown in diagrams other than FIG. 2.

In embodiments of the present invention VC section 56 may have any suitable number of pillars 52 in any suitable array. Thus, in the embodiment seen in FIG. 2, in section 56A there are 36 pillars in a rectangular 6×6 array. In other embodiments, in sections 56 described below there may be other numbers of pillars, and they may be arranged in a non-rectangular array, for example a triangular array.

The components of a given lid 32 may be formed from any suitable high thermally conducting material, such as copper, silver, and/or diamond, and the lid may comprise one or more than one such material. By way of example, FIG. 2 illustrates a condenser 44A formed of copper and an evaporator 40A formed of a diamond sheet. However, it is noted that condenser 44A may be made of high conducting material other than copper, and evaporator 40A may be made of high conducting material other than diamond.

Table I below provides a range of dimensions of elements of lids 32, according to a disclosed embodiment of the present invention. Other embodiments of the present invention may have values for these elements outside the ranges given in Table I.

TABLE I

| Element | Range | |
|---|---|---|
| Condenser wall thickness | 1-1.5 | mm |
| Evaporator wall thickness | 1-1.5 | mm |
| Condenser wick thickness | 0.1-0.4 | mm |
| Evaporator wick thickness | 0.1-0.4 | mm |
| Wick porosity | 0.4-0.7 | |
| Pillar diameter | 1-4 | mm |
| Pillar pitch (distance | 4-6 | mm |
| between nearest neighbors) | | |
| Thickness of wicking | 0.1-0.3 | mm |
| material around pillars | | |

Using the values of Table I, embodiments of the present invention achieve the values given in Table II, when a given lid 32 is operating. The values are achieved for heat transmission through the given lid at powers equal to, or greater than, 150 W.

TABLE II

| Property | Value | |
|---|---|---|
| Deviation from flatness of | ≤100 | μm |
| cover 40 and base 44 | | |
| external surfaces | | |
| Internal pressure of volume 58 | 40 | bar |

As stated above, the dies of micro-device packages, such as package 122, are provided with a vapor chamber lid, such as lid 32A, to protect the components. In the following description, for simplicity and clarity, except where otherwise stated, the micro-devices are assumed to comprise integrated circuits (ICs), and the packages are termed IC packages. Those having ordinary skill in the art will be able to adapt the description, mutatis mutandis, to encompass packages of dies of other types of micro-devices, such as optical components and optoelectronic components including lasers, laser arrays, photodiodes, photodiode arrays, as well as transimpedance amplifiers (TIAs), Drivers, Silicon Photonics, and application specific integrated circuit (ASIC) switches.

### IC Packages Having a Single Die

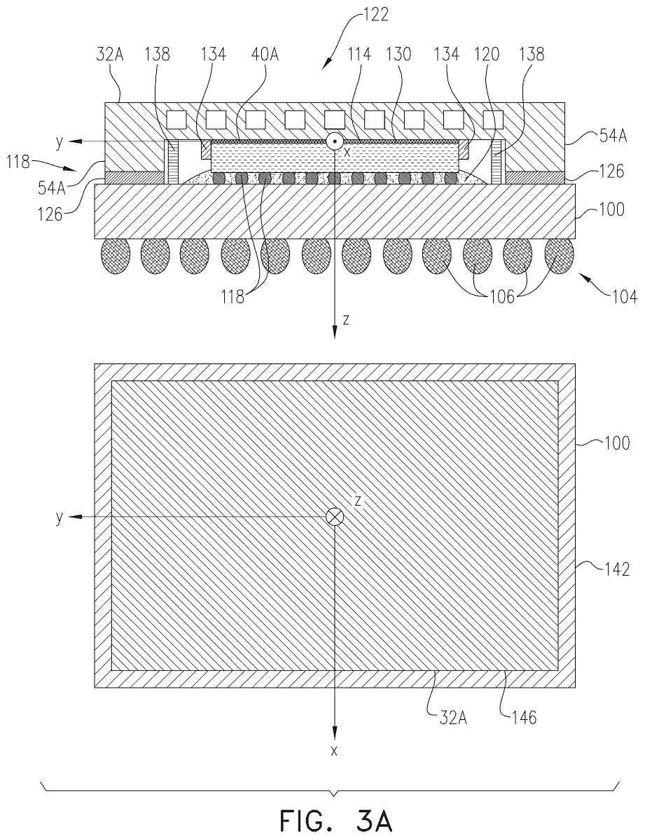

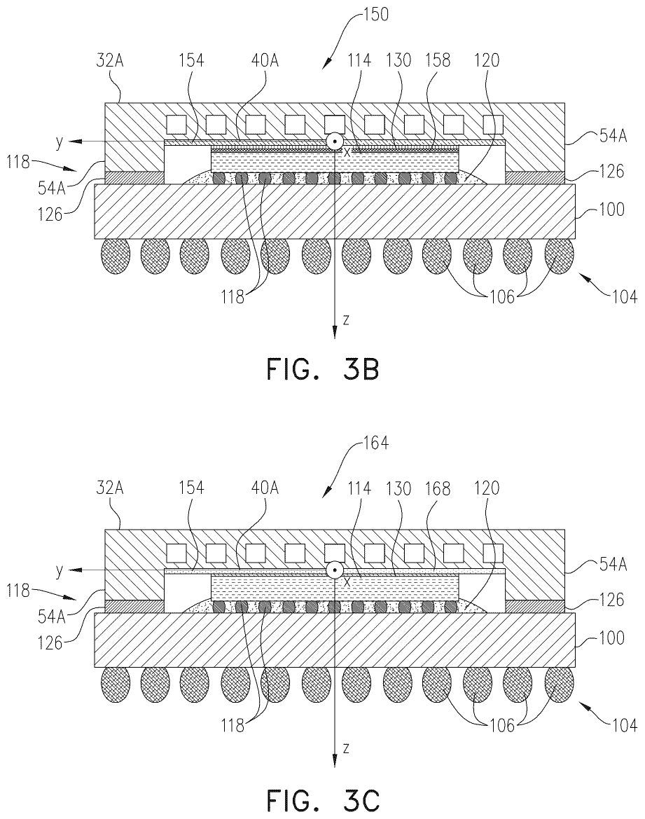

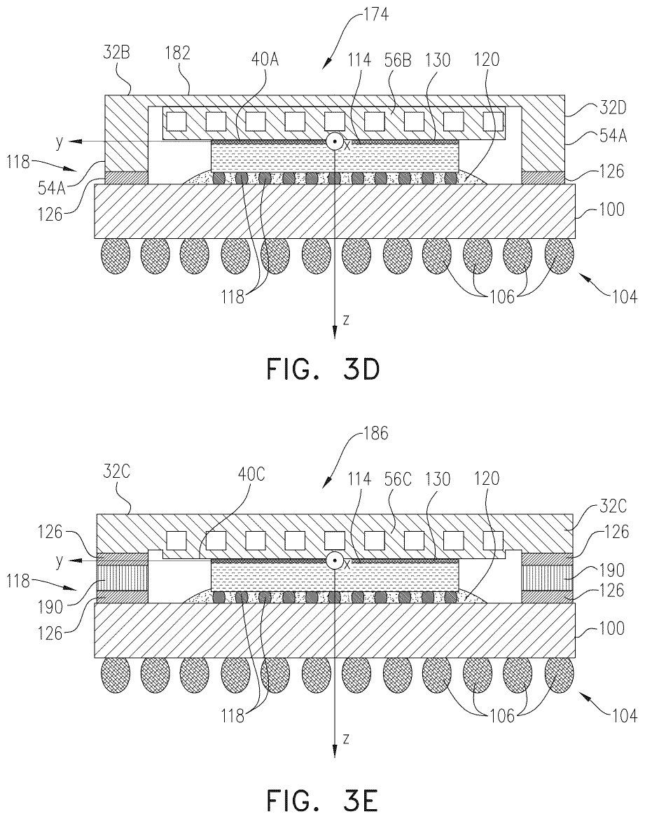

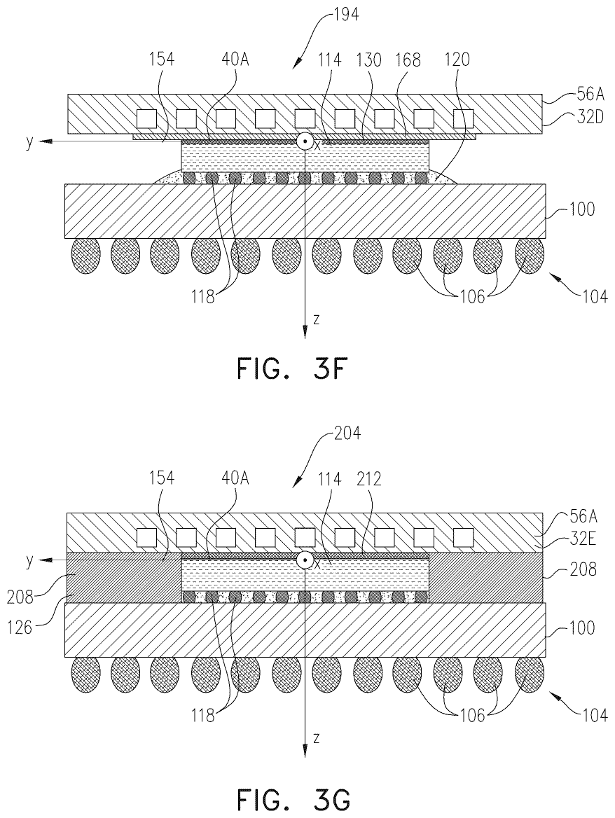

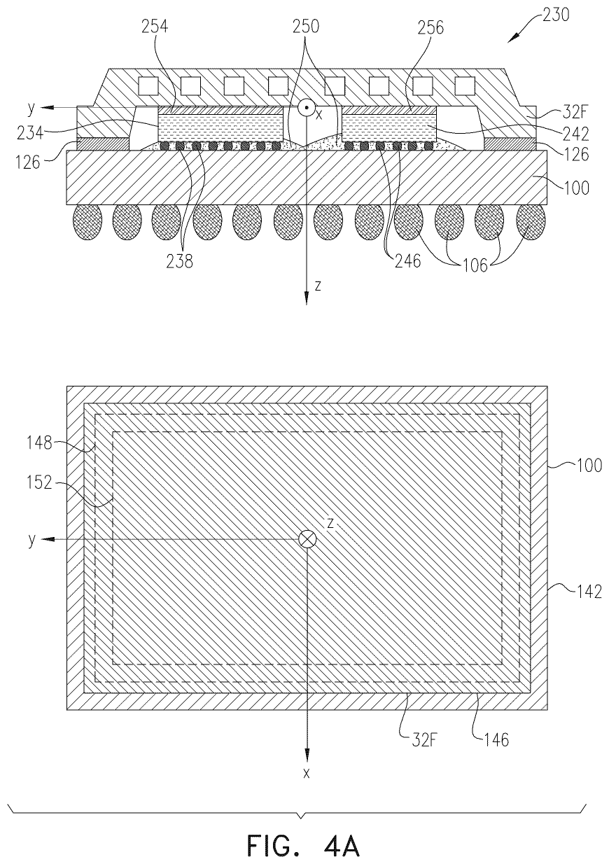

FIGS. 3A-3G are schematic diagrams of IC packages, according to embodiments of the present invention. For simplicity, each IC package is assumed to be formed on a substantially similar rectangular substrate 100 which has a substrate ball grid array (BGA) 104 of solder balls 106 attached to the underside of the substrate. In addition, each IC package comprises an integrated circuit (IC) die 114, also referred to herein as IC 114. IC 114 has an integrated circuit ball grid array (ICBGA) of copper and solder bumps 118, also herein termed surface mount terminals 118, positioned to contact the upper surface of substrate 100. Underfill material 120, comprising any convenient underfill material known in the art, surrounds solder bumps 118.

In the embodiments described with reference to FIGS. 3A-3G each vapor chamber lid 32 is generally constructed and functions, unless stated otherwise, as lid 32A, and comprises elements of lid 32A, e.g., cover 40A.

FIG. 3A illustrates IC package 122 in a cross-sectional view, viewing into the x-axis and a top-down view, viewing along the z-axis. In package 122, lid 32A is formed with wall extensions 54A, and the extensions are used to attach the lid to substrate 100 using a seal adhesive 126. Prior to the attachment, the lower surface of lid cover 40A may be positioned to thermally couple to an upper surface of IC 114, with a sheet 130 of thermal interface material (TIM) between the two surfaces facilitating the contact. Sheet 130 may comprise any suitable TIM known in the art, such as, but not limited to, solid or liquid metal TIM, polymer, graphite and the like.

In an alternative embodiment of package 122, cover 40A may be formed to have downward protrusions 134, which are configured to enclose the sides of IC 114 and to serve as a TIM containment barrier. By ensuring containment of a TIM material 130 between IC 114 and lid 32A, protrusions 134 may enhance heat transfer from IC 114 to lid 32A, for instance by facilitating the use of TIM materials that may not be solid at operating temperatures, which in some applications may offer improved heat transfer properties in relation to solid TIM.

In a further alternative embodiment of package 122, the package may be formed with TIM containment barriers 138 between lid 32A and substrate. Barriers 138 facilitate retention of the material of TIM sheet 130 in proximity to IC 114.

As is shown in the top-down view, a perimeter 142 of a projection of substrate 100 onto an xy plane completely encloses a perimeter 146 of a projection of lid 32A onto the xy plane. Perimeter 142 is also termed package footprint 142 and perimeter 146 is also termed lid footprint 146; as is illustrated in the top-down view of FIG. 3A, lid footprint 146 is smaller than, and is completely enclosed by, package footprint 142.

FIGS. 3B-3G illustrate cross-sectional views of additional IC packages. The additional IC packages have substantially the same top-down view as package 122, so that for each additional IC package the lid footprint is smaller than, and is completely enclosed by, the substrate footprint. Except as described hereinbelow, the construction and functionality of the further IC packages are substantially the same as the construction and functionality of package 122 comprising VC lid 32A.

FIG. 3B illustrates a cross-sectional view of an IC package 150 viewing into the x-axis. In package 150, the lower surface of cover 40A, and the upper surface of IC 114 are metallized, with respective metal surfaces 154 and 158. Surfaces 154 and 158 improve the thermal transfer of TIM sheet 130, and the material of the surfaces is selected to be compatible with TIM sheet 130. In a disclosed embodiment metal surface 154 comprises gold or other suitable material, metal surface 158 comprises silver, and TIM sheet 130 is formed of metal TIM.

FIG. 3C illustrates a cross-sectional view of an IC package 164, viewed into the x-axis. In package 164 a sheet 168 of a highly thermally conductive material, such as diamond, is used as cover 40A, for instance as an evaporator. Sheet 168 may be dimensioned to serve as the whole of wall 40A, or alternatively may only contact part of the wall. When implemented to serve as the wall, the part contacted may correspond to a hotspot region of IC 114.

An evaporator wick for package 164 (corresponding to evaporator wick 64A described above with reference to FIG. 2) may also be formed of the high thermal conductive material. In some embodiments the whole of lid 32A may be formed from the highly conductive material.

Using the highly thermally conductive material may improve the thermal management of package 164.

FIG. 3D illustrates a cross-sectional view of an IC package 174, viewed into the x-axis. Package 174 comprises a lid 32B which, except as described below, is substantially similar in construction and operation to lid 32A (presented with reference to FIG. 2). In package 174 lid 32B may be formed in two or more pieces, rather than the single piece of lid 32A. By way of example, as is illustrated in FIG. 3D, lid 32B is formed of a vapor chamber section 56B, substantially similar to VC section 56A (FIG. 2), and that is separate from, but is connected, to a retainer 182. Retainer 182 is dimensioned so that when connected to VC section 56B, the combined structure of the VC section and the retainer may be mounted on substrate 100, as illustrated in the figure.

Forming a VC lid in two or more pieces may facilitate the production and/or the assembly of the IC package using the lid.

FIG. 3E illustrates a cross-sectional view of an IC package 186, viewed into the x-axis. Package 186 comprises a lid 32C which extends laterally compared to lid 32A and which, rather than having wall extensions 54A, comprises stiffeners 190, which attach a VC section 56C to substrate 100 via adhesives 126 implemented both above and below the stiffeners. Stiffeners 190 are dimensioned so that the lower surface of a lid cover 40C couples to the upper surface of IC 114 via TIM sheet 130. To implement the coupling, an external surface of cover 40C may or may not lowered, compared to the external surface of cover 40A, as shown in the figure. When there is lowering, such a lowering increases the volume of the vapor space of a VC section 56C. Alternatively, if the external surface of the cover is not lowered, the vertical dimension of the stiffeners may be reduced to implement the coupling of cover 40C to IC 114.

FIG. 3F illustrates a cross-sectional view of an IC package 194, viewed into the x-axis. Except as described below, package 194 is substantially similar in function and construction to IC package 164 (described above with reference to FIG. 3C). However, in package 194, wall extensions 54A are not implemented, so that a lid 32D of the package only consists of VC section 56A.

FIG. 3G illustrates a cross-sectional view of an IC package 204, viewed into the x-axis. In package 204 a lid 32E of the package comprises VC section 56A, typically extended laterally as described above with reference to FIG. 3E, coupled to a mold 208 that is mounted on substrate 100. The mold is configured to retain IC 114, and, in addition, when the package is assembled, a TIM sheet 212 may be located between the lower surface of cover 40A and the upper surface of IC 114

FIGS. 3A-3G illustrate embodiments of the present invention where a VC lid is used for the heat management of an IC package that has a single die. Embodiments of the present invention may also be implemented for the heat management of multiple dies, as is described below.

The following description refers to integrated circuit packages having multiple dies. Those having ordinary skill in the art will be able to adapt the description, mutatis mutandis, for packages where the micro-devices of the packages are only integrated circuits, are only optoelectronic components, are only optical components, or are mixtures of integrated circuits and/or optoelectronic components and/or optical components, and all such packages are assumed to be comprised within the scope of the present invention.

### IC Packages Having Multiple Dies

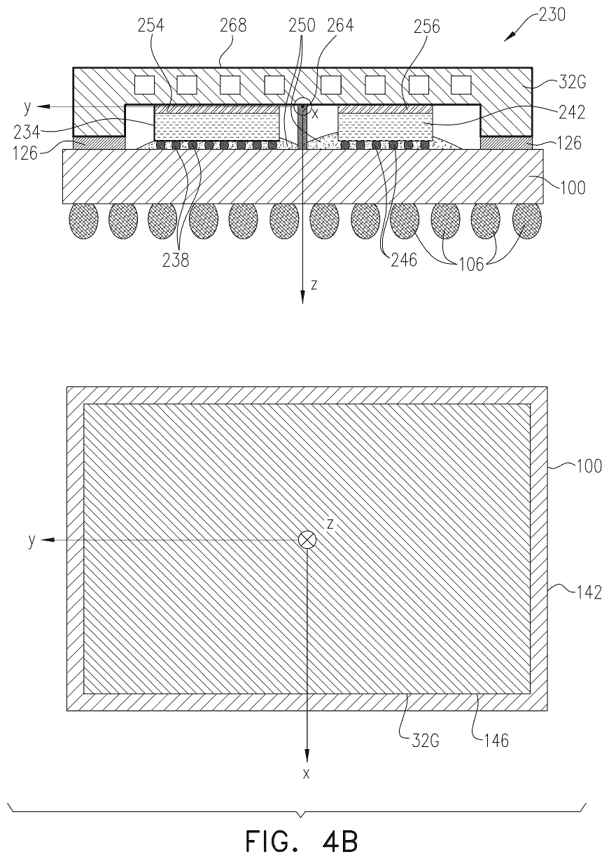

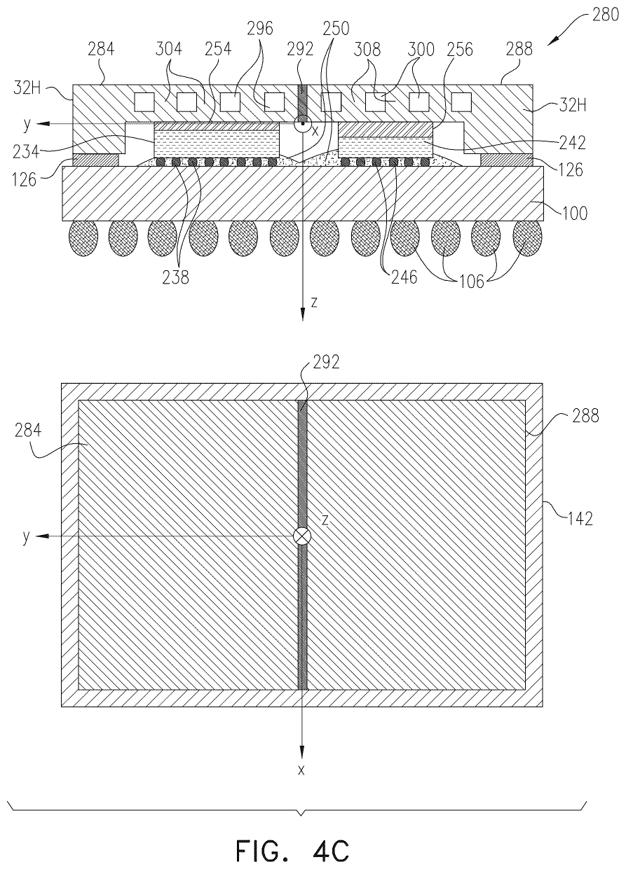

FIGS. 4A-4C are schematic diagrams of IC packages comprising multiple dies, according to embodiments of the present invention. While the examples below describe packages with two dies, those with ordinary skill in the art will be able to adapt the description, mutatis mutandis, for packages having more than two dies, and all such packages are assumed to be comprised within the scope of the present invention.

FIG. 4A illustrates a cross-sectional view of an IC package 230 viewing into the x-axis, and a top-down view. In contrast to the packages described above, where the VC lid is flat-topped and has a general “coin-shape,” i.e., a yz cross-section has edges that are only either parallel to the y-axis or parallel to the z-axis, package 230 comprises a VC lid 32F that is generally “hat-shaped”, i.e., wherein a yz cross-section has some edges that are not parallel to either the y-axis or the z-axis. Apart from the shape difference, VC lid 32F has generally the same functionality and construction as VC lid 32A.

Package 230 has substantially the same top-down view as IC package 122, as shown in FIG. 3A, except that edges of lid 32F within lid perimeter 146 are shown as rectangles 148 and 152.

Package 230 comprises two separate dies: a die 234 having an ICBGA 238, and a die 242 having an ICBGA 246. ICBGA 238 and ICBGA 246 are surrounded by underfill material 250, and the dies are retained in contact with a lower surface of lid 32F by TIM sheets 254 and 256.

FIG. 4B illustrates a cross-sectional view of an IC package 260 viewing into the x-axis, and a top-down view of the package. Except as described herein, package 260 is generally similar in construction and functionality to package 230 (FIG. 4A). However, a VC lid 32G of package 260 is coin-shaped, having a top-down view substantially the same as that of package 122 (FIG. 3A). In addition, package 260 comprises an electromagnetic shield 264 between dies 234 and 242. The electromagnetic shielding of the dies may be further enhanced by providing VC lid 32G with an electromagnetic coating 268 on the surface of the lid. The electromagnetic material used for shield 264 and coating 268 may comprise any suitable material, such as nickel or stainless steel. Shield 264 and coating 268 reduce electromagnetic fields traversing die 234 and/or die 242. The fields may be generated by the dies and/or may be generated externally to, and received by, the dies.

FIG. 4C illustrates a cross-sectional view of an IC package 280 viewing into the x-axis, and a top-down view of the package. Except as described herein, package 280 is generally similar in construction and functionality to package 230 (FIG. 4A). In contrast to package 230 package 280 comprises a VC lid 32H which is coin-shaped and which is in two parts—a first part, a sub-vapor chamber lid 284, and a second part, a sub-vapor chamber lid 288—joined and fixedly connected by a mold 292. As illustrated in the figure, each sub-vapor chamber lid comprises a separate sub-vapor chamber 296, 300, and separate pillars 304, 308 for the sub-vapor chamber.

Forming VC lid 32H in two parts may facilitate production of package 280, and it will be understood that forming a VC in more than two parts may further facilitate production. Thus, the scope of the present invention comprises forming VC lids in a plurality of separate parts.

In embodiments described above, the perimeter of the top-down view of the VC lids comprises a rectangle and the lids appear as planar sheets having a single continuous surface. However, embodiments of the present invention may have one or more apertures in the VC lid, and/or non-rectangular perimeters, as is described below.

### IC Packages Having an Aperture in the VC Lid

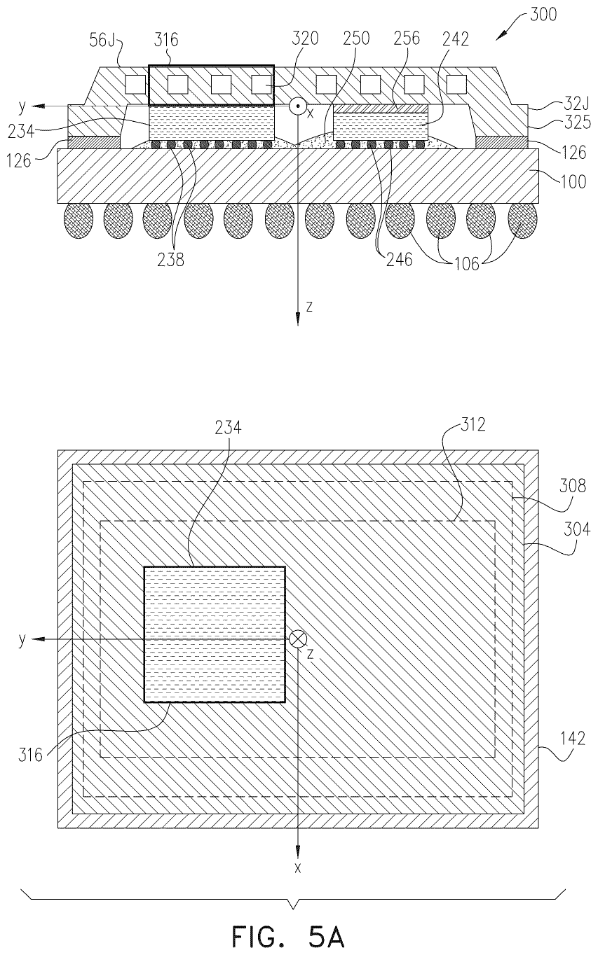

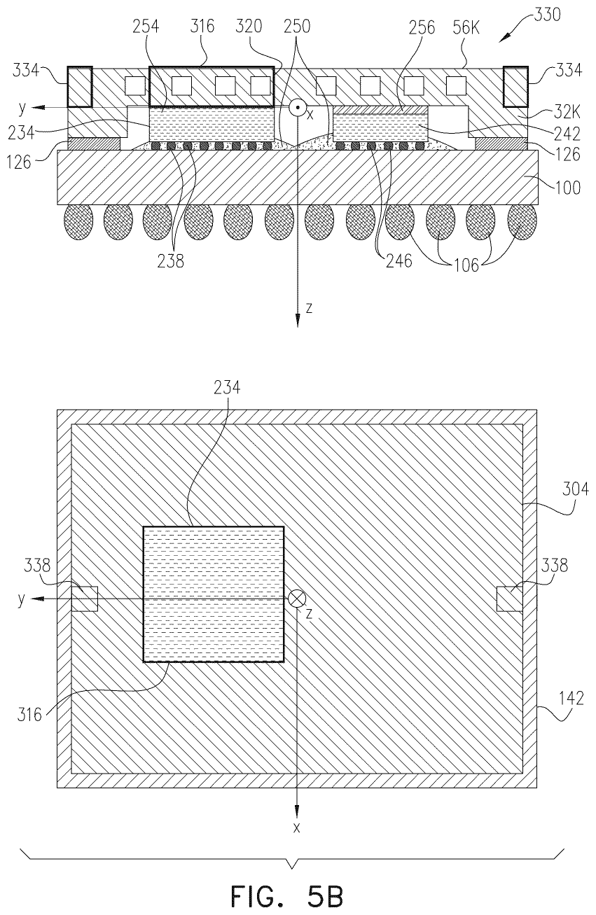

FIGS. 5A and 5B are schematic diagrams of IC packages having a single aperture in a VC lid, according to embodiments of the present invention. While the examples below describe packages with a single aperture in the lid, those with ordinary skill in the art will be able to adapt the description, mutatis mutandis, for packages having two or more lid apertures, and all such packages are assumed to be comprised within the scope of the present invention.

FIG. 5A illustrates a cross-sectional view of an IC package 300 viewing into the x-axis, and a top-down view of the package. Package 300 comprises a VC lid 32J, which may be hat-shaped and which, except as described below, is generally similar in construction and functionality to VC lid 32F (FIG. 4A). The top-down view shows the perimeter of lid 32J as a rectangle 304, and the edges of the hat shape as rectangles 308 and 312. In an alternative embodiment of package 300, VC lid 32J is coin shaped, in which case the top-down view does not have rectangles 308 and 312.

In contrast to VC lid 32F, VC lid 32J comprises an aperture 316 in a VC section 56J of lid 32J. To form the aperture, walls 320 are constructed between the planar base of the cup-shaped portion of the lid and the cover of the lid. The walls are configured so that even though aperture 316 may be open to the atmosphere, the integrity of the internal volume containing the fluid of lid 32J is maintained. I.e., there is no leakage of fluid from the lid's internal volume.

FIG. 5A illustrates that aperture 316 is above die 234 so that a full vapor chamber is disposed over IC 242, while IC 234 is exposed to the environment. This configuration enables lid 32J to accommodate differential heat exchange capacities in response to different heat generating attributes of IC components 234 and 242.

FIG. 5B illustrates a cross-sectional view of an IC package 330 viewing into the x-axis, and a top-down view.

Package 330 comprises a VC lid 32K which is coin-shaped and which, except as described below, has generally similar construction and function as the hat-shaped embodiment of VC lid 32J (FIG. 5A). In package 330 there are, by way of example, two cutout sections 334 in a VC section 56K of lid 32K, and these cutout sections are presented as rectangles 338 in the top-down view. Other embodiments may have more or fewer than two cutout sections.

Cutout sections such as sections 334 provide different heat dissipations for the areas beneath the cutouts, thus accommodating components that have different heat generating capacities.

### Further IC Packages

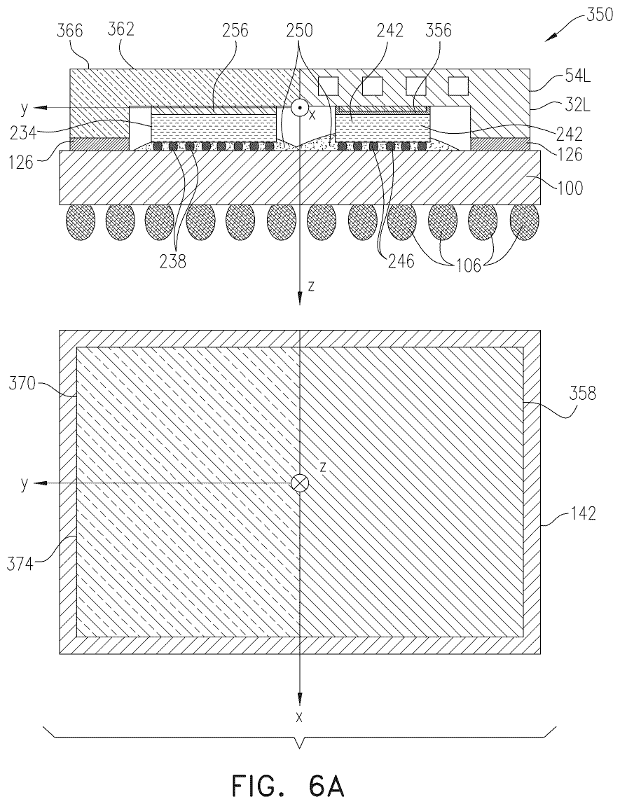

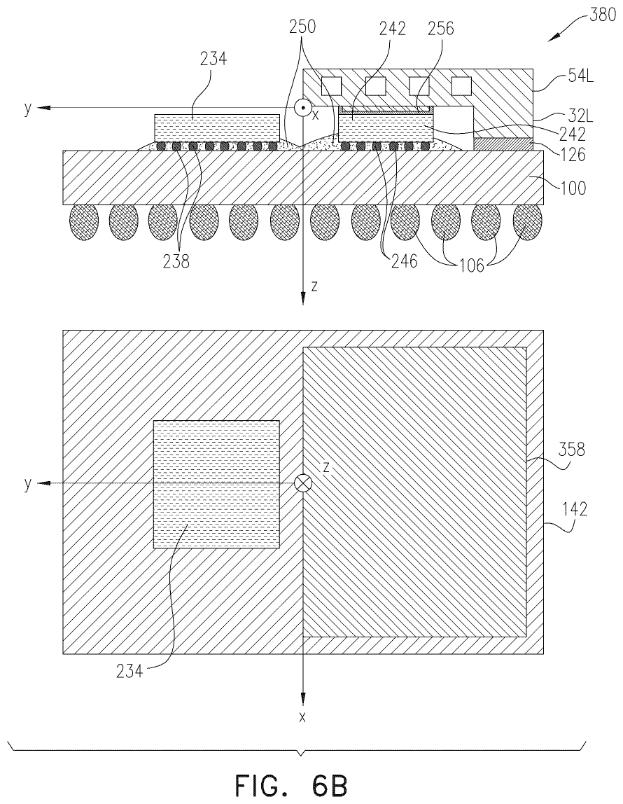

FIGS. 6A and 6B are schematic diagrams of IC packages having multiple dies and a partial VC lid, according to embodiments of the present invention.

FIG. 6A illustrates a cross-sectional view of an IC package 350 viewing into the x-axis, and a top-down view of the package. In contrast to other IC packages described herein, package 350 comprises a partial VC lid 32L, wherein a perimeter 358 of the partial VC lid does not encompass all of the dies, herein dies 234 and 242, of the package. Partial VC lid 32L functions generally as VC Lid 32A, and except for being smaller and having only one wall extension 54L, is generally constructed as VC lid 32A.

In the embodiment illustrated a lid 362 of the package is formed by coupling another thermally conductive partial lid 366, for example one made of copper, that does not have a vapor chamber, to partial VC lid 32L. Partial lid 366 has a perimeter 370, seen in the top-down view. Partial lid 366 acts as a heat sink for die 234, and has generally the same shape as partial VC lid 32L. In a disclosed embodiment the shapes of partial lid 266 and VC partial lid 32L are mirror images in an xz plane. Partial VC lid 32L acts as a heat sink for die 242. As illustrated in the figure, die 242 is retained in contact with a lower surface of a VC portion 56L of partial lid 32L by a TIM sheet 356, and die 234 is retained in contact with a lower surface of partial lid 366 by TIM sheet 256.

As is illustrated in the figure, an overall perimeter 374 of the combination of partial lid 366 and partial VC 32L is enclosed by perimeter 142 of the substrate.

FIG. 6B illustrates a cross-sectional view of an IC package 380 viewing into the x-axis, and a top-down view. Except as described below, packages 350 (FIG. 6A) and 380 are generally similar in construction and functionality. Thus, both packages comprise partial VC lid 32L. However, in package 380 die 234 has no need for a heat sink, so that partial lid 366 is absent and the die is visible in the top-down view. IC package 380 only comprises partial VC lid 32L for a heat sink.

In package 380 perimeter 358 of partial VC lid 32L is enclosed by perimeter 142 of the substrate.

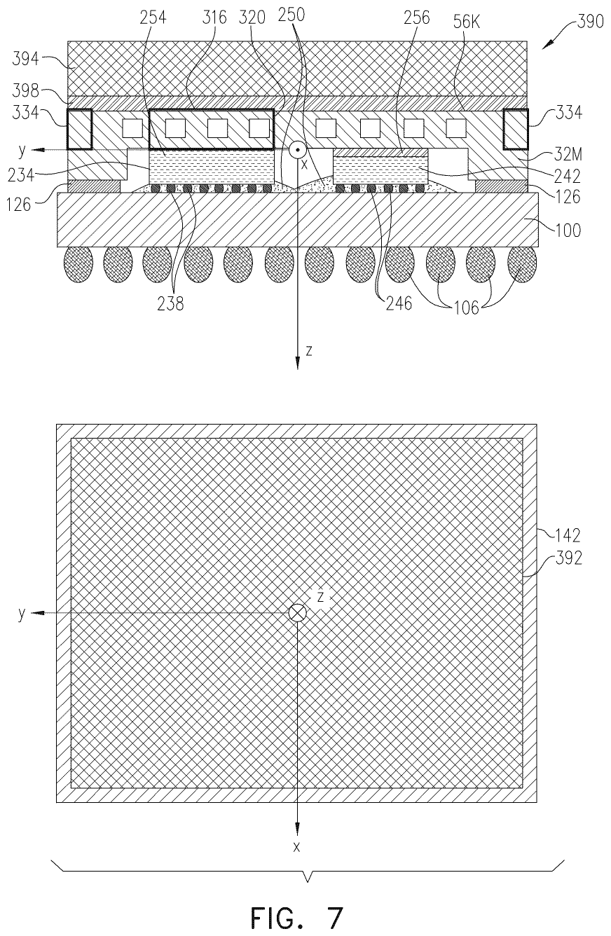

Embodiments described above use one two-phase flow device, the vapor chamber lid of the device. However, it will be understood that the scope of the present invention is not limited to using just one two-phase flow device, as is seen in examples below for the IC package described with reference to FIG. 7.

FIG. 7 is a schematic diagram of an IC package 390 having multiple dies and a VC lid coupled to another two-phase flow device, according to an embodiment of the present invention. The figure shows a cross-sectional view of package 390 viewing into the x-axis, and a top-down view of the package. IC package 390 uses a VC lid 32M that is substantially similar in construction and function to any of the complete VC lids described herein. Thus, for clarity, except for the differences described herein, VC lid 32M is assumed to be substantially similar to VC lid 32K, and package 390 is assumed to be similar to package 330; VC lid 32K and IC package 330 are described above with reference to FIG. 5B.

Coupled to an upper surface of VC lid 32M is a second two-phase flow device 394, which has a perimeter 392 in the top-down view. Device 394 may comprise another VC, a heat pipe and/or a thermosiphon. The coupling may be by attaching the surfaces of the two devices using a TIM sheet 398. Alternatively, the coupling may be by bonding the two surfaces.

Second flow device 394 improves the overall heat transfer from the dies of package 390 and so may reduce the temperature of the condenser wall of VC lid 32M.

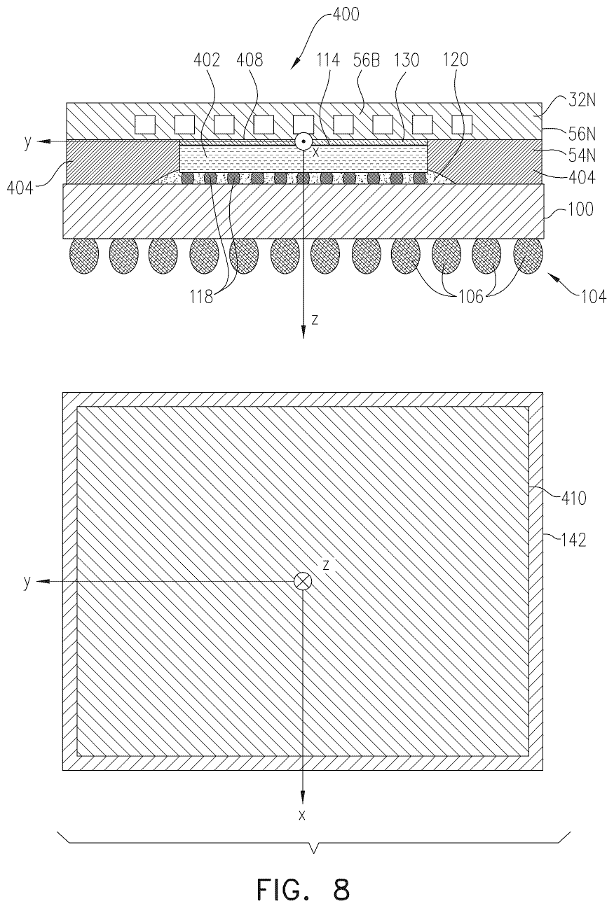

In some embodiments an exposed die that is encased in a mold may be available for packaging “as is”. FIG. 8 is a schematic cross-sectional view and a top-down view of an IC package 400 wherein a VC lid 32N is mounted on a die formed with a mold, according to an embodiment of the present invention. In the illustrated embodiment, a die 402 is shown as being encased in a mold 404, and the die and the mold are attached to substrate 100. In package 400, wall extensions are not implemented, so that VC lid 32N of the package only consists of a VC section 56N and has a perimeter 410 in the top-down view. VC section 56N overlays die 402 and is coupled to the die by a TIM sheet 408. VC section 56N is also attached to mold 404, and the attachment adds to the mechanical stability of the package.

In the embodiments described hereinabove, and as illustrated in FIG. 2, the VC section of each VC lid is formed between two planar conducting sheets—a planar base and a planar cover, so that the VC section is substantially two-dimensional (2D). In some embodiments the VC section may be three-dimensional (3D), as is exemplified in the following description of an IC package 420.

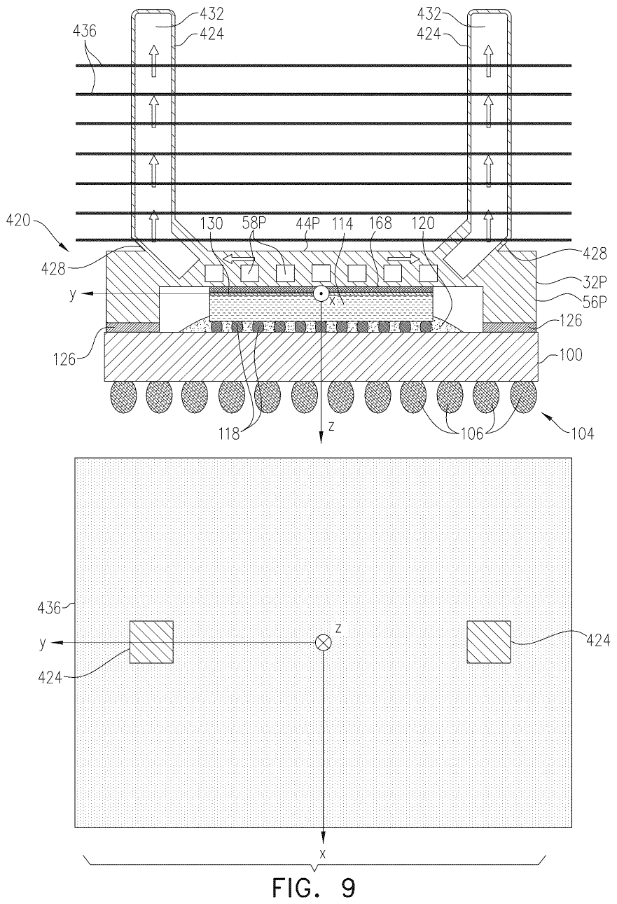

FIG. 9 is a schematic diagram of IC package 420, wherein a VC lid of the package is coupled to a finned structure, according to an embodiment of the present invention. The figure illustrates a cross-sectional and a top-down view of IC package 420. Package 420 is formed with a VC lid 32P, which has generally similar functions as other VC lids described herein, and which is, except as described below, generally similar in construction and function to VC lid 32A (FIG. 3C), described above. However, as shown in the cross-sectional view, two generally similar closed tubular structures 424 (such as heat pipes) extend from a condenser wall 44P—the upper surface—of a VC section 56P of the lid.

Tubular structures 424 are generally normal to the upper surface of section 56P. In an alternative embodiment, joints 428 connecting structures 424 to section 56P make a non-normal angle, for example 45°, with the section. The structures are formed so that their internal volumes 432 couple to an internal volume 58P of VC section 56P, and so that there is no leakage of fluid from any of the coupled volumes. The arrows in the coupled volumes illustrate the direction of flow of hot fluid within the volumes; cooled fluid flows in the coupled volumes in the opposite direction.

The internal elements of VC section 56P are wicked, and wicking is typically also applied to the internal surfaces of structures 424.

The construction of structures 424 effectively increases the area of condenser wall 44P, thereby improving the heat transfer properties of VC lid 32P compared to lids without the structures. The heat transfer properties may be further increased by attaching thermally conductive fins 436, generally parallel to the upper surface of section 56P, to structures 424.

While IC package 420 is illustrated as having two structures 424, it is noted that other numbers of structures, including just one such structure, may be used, and all such other numbers of structures are included within the scope of the present invention.

It is noted that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An electronic device package, comprising:
a planar package substrate defining a package footprint;
one or more micro-devices surface mounted on and configured to electrically couple to the package substrate via an array of surface mount terminals; and
a vapor chamber lid overlaying the one or more micro-devices and having planar dimensions that are smaller than the package footprint.

2. The electronic device package according to claim 1, wherein the surface mount terminals comprise balls arranged in an array.

3. The electronic device package according to claim 1, further comprising stiffeners coupled between the vapor chamber lid and the substrate.

4. The electronic device package according to claim 1, wherein the one or more micro-devices comprise a given micro-device having a surface overlayed by the vapor chamber lid, and wherein the vapor chamber lid comprises protrusions orthogonal to the surface and enclosing the given micro-device so as to form a containment space for thermal interface material.

5. The electronic device package according to claim 1, wherein the one or more micro-devices comprise a given micro-device formed with a mold, and wherein the mold is configured to connect with the vapor chamber lid and with the substrate.

6. The electronic device package according to claim 1, further comprising a thermal interface material (TIM) interposed between and contacting the one or more micro-devices and the vapor chamber lid, the package further comprising TIM retention containment barriers between the lid and the substrate.

7. The electronic device package according to claim 1, and further comprising a coating on a surface of the vapor chamber lid, the coating being configured to reduce electromagnetic emissions traversing the one or more micro-devices.

8. The electronic device package according to claim 7, wherein the one or more micro-devices comprise a plurality of micro-devices, the package further comprising an electromagnetic shield between the plurality of micro-devices, configured to reduce electromagnetic emissions between the micro-devices.

9. The electronic device package according to claim 1, wherein the vapor chamber lid comprises a plurality of sub-vapor chamber lids joined and fixedly connected by a mold.

10. The electronic device package according to claim 1, wherein the one or more micro-devices comprise a first micro-device and a second micro-device, and wherein the vapor chamber lid comprises an aperture aligning with the first micro-device so that the vapor lid contacts the second micro-device ponent without contacting the first micro-device.

11. The electronic device package according to claim 1 and comprising at least one additional micro-device mounted on and configured to electrically couple to the package substrate via an additional array of surface mount terminals, wherein the vapor chamber lid overlays the one or more micro-devices without overlaying the at least one additional micro-device.

12. The electronic device package according to claim 11, and comprising a thermally conductive lid that is absent a vapor chamber, the thermally conductive lid being configured to overlay the at least one additional micro-device.

13. The electronic device package according to claim 1 and comprising a two-phase flow device, and wherein the vapor chamber lid comprises a first surface contacting the one or more micro-devices and a second surface contacting the two-phase flow device.

14. The electronic device package according to claim 1, wherein the vapor chamber lid comprises a planar section, configured to contact surfaces of the one or more micro-devices, and at least one tubular section orthogonal to the planar section, wherein the planar section and the at least one tubular section have a common vapor chamber, and wherein thermally conductive fins are attached to the at least one tubular section.

15. The electronic device package according to claim 1, wherein the one or more micro-devices comprise at least one of an integrated circuit and an optoelectronic component.

16. A method, comprising:
providing a planar package substrate defining a package footprint;
surface mounting one or more micro-devices on the package substrate;
electrically coupling, via an array of surface mount terminals, the one or more micro-devices to the package substrate; and
overlaying a vapor chamber lid on the one or more micro-devices, wherein the vapor chamber lid has planar dimensions that are smaller than the package footprint.

17. The method according to claim 16, wherein the surface mount terminals comprise balls arranged in the array.

18. The method according to claim 16, further comprising coupling stiffeners between the vapor chamber lid and the substrate.

19. The method according to claim 16, wherein the one or more micro-devices comprise a given micro-device having a surface overlayed by the vapor chamber lid, and wherein the vapor chamber lid comprises protrusions orthogonal to the surface and enclosing the given micro-device so as to form a containment space for thermal interface material.

20. The method according to claim 16, wherein the one or more micro-devices comprise a given micro-device formed with a mold, the method further comprising connecting the vapor chamber lid and the substrate with the mold.

21. The method according to claim 16, wherein the vapor chamber lid comprises a plurality of sub-vapor chamber lids, the method further comprising joining and fixedly connecting the plurality of sub-vapor chamber lids by a mold.

22. The method according to claim 16, wherein the one or more micro-devices comprise a first micro-device and a second micro-device, and wherein the vapor chamber lid comprises an aperture aligning with the first micro-device so that the vapor lid contacts the second micro-device without contacting the first micro-device.
